(19) United States
(12) Patent Application Publication
(10) Pub. No.: US 2014/0071602 A1
(43) Pub. Date: Mar. 13, 2014

(54) POWER CABLE MANAGEMENT IN AN ELECTRONIC COMPONENT STORAGE RACK

(71) Applicants: Shareef F. Alshinnawi, Durham, NC (US); Gary D. Cudak, Creedmoor, NC (US); Edward S. Suffern, Chapel Hill, NC (US); J. Mark Weber, Wake Forest, NC (US)

(72) Inventors: Shareef F. Alshinnawi, Durham, NC (US); Gary D. Cudak, Creedmoor, NC (US); Edward S. Suffern, Chapel Hill, NC (US); J. Mark Weber, Wake Forest, NC (US)

(73) Assignee: INTERNATIONAL BUSINESS MACHINES CORPORATION, Armonk, NY (US)

(21) Appl. No.: 13/610,079

(22) Filed: Sep. 11, 2012

(51) Int. Cl. H05K 7/02

(52) U.S. Cl. 361/679.02

(57) ABSTRACT

A computer storage rack has vertically arranged bays for receiving electrical power-consuming components, an elongate electrical power distribution unit (PDU) having power distribution sockets vertically spaced along the length of the PDU, and a hinge pivotally coupling the PDU to the rack along a vertical axis. The PDU pivots about the hinge between a position proximal to the bays and a position distal to the bays. The apparatus further comprises a component power supply cables that are resiliently extendable from a collapsed configuration to an extended configuration. Each of the component power supply cables is connected between one of the power distribution sockets and an adjacent one of the electrical power-consuming components, and each is resiliently extendable in response to pivoting the PDU to the distal position and resiliently collapsed in response to pivoting the PDU to the proximal position.

### BACKGROUND OF THE INVENTION

1. Field of the Invention

The present invention relates to electronic component storage racks. More specifically, the present invention relates to a power cable management system for an electronic component storage rack supporting a plurality of electrical power-consuming components.

2. Background of the Related Art

Modern computer systems include electronic component storage racks, or server racks, constructed to support a plurality of electrical power-consuming components, such as servers, within the rack. The rack generally comprises a front door, a back door, and a plurality of vertical members connected to a plurality of horizontal rails defining bays into which electrical power-consuming components may be installed. The installed components may be cabled to receive and provide data and to receive electrical current through power supply cables connected thereto.

Generally, racks are constructed to facilitate the convenient installation and removal of components into and from the bays. A component is generally installed to dispose a power supply connector towards a door of the rack so that a power supply cable can be conveniently connected to the installed component, and so that the power supply cable can be easily disconnected from the component upon removal of the component from the bay. Components supported in a rack are generally installed and/or programmed to facilitate continued operation of remaining components while an individual component is removed for service or replaced.

Most components have data connectors to transmit data to external sources and receive data from external sources, and a power supply connector to receive electrical current necessary to operate the component. Data cables may be interconnected with a remote component, or data cables may be interconnected from one component within the rack to another component within the same rack. Power supply cables generally provide current from a remote power supply source to a power supply connector on the component, where the connector is disposed towards a door of the rack. This arrangement requires that each of a plurality of power supply cables be connected between a power distribution unit (PDU) and the connector on one of the components.

### BRIEF SUMMARY OF THE INVENTION

One embodiment of the present invention provides an apparatus comprising a computer storage rack having a plurality of vertically arranged bays for receiving a plurality of electrical power-consuming components, an elongate electrical power distribution unit having a plurality of power distribution sockets vertically spaced along the length of the power distribution unit, and a hinge pivotally coupling the power distribution unit to the rack along a vertical axis, wherein the power distribution unit pivots about the hinge between a position proximal to the bays of the rack and a position distal to the bays of the rack. The apparatus further comprises a plurality of component power supply cables that are resiliently extendable from a collapsed configuration to an extended configuration, wherein each of the component power supply cables is connected between one of the power distribution sockets and an adjacent one of the electrical power-consuming components, and wherein each of the component power supply cables are resiliently extendable to the extended configuration in response to pivoting the power distribution unit to the distal position and resiliently restored to the collapsed configuration in response to pivoting the power distribution unit to the proximal position.

### BRIEF DESCRIPTION OF THE SEVERAL VIEWS OF THE DRAWINGS

FIG. 1 is a perspective view of an electronic component storage rack having a door pivotally coupled to a vertical member of the rack using hinges.

FIG. 2 is a schematic side view of an electronic component storage rack having a power distribution unit disposed in a vertical orientation and secured to a door that is pivotally coupled to the rack.

FIG. 3 is a schematic plan view of the power distribution unit and electronic component storage rack of FIG. 2 after the door of the rack is pivoted about the hinge to a closed position.

FIG. 4 is a schematic side view of the apparatus in FIG. 3 revealing the plurality of component power supply cables in the collapsed configuration and residing in a space laterally adjacent to the component bays of the rack.

FIG. 5 is a diagram of an individual component power supply cable that can be used in connection with embodiments of the present invention in an extended configuration corresponding to the open position of the door illustrated in FIG. 2.

FIG. 6 is a diagram of the power supply cable of FIG. 5 in a partially collapsed configuration corresponding to closed position of the door as illustrated in FIGS. 3 and 4.

FIG. 7 is a diagram of a power supply cable that collapses into a tortuous path when the door is pivoted to a closed position.

FIG. 8 is a schematic plan view of an alternative embodiment having a power distribution unit (PDU) coupled by a PDU hinge to a door that is hingedly coupled to an electronic component storage rack, wherein the door is closed to position the power distribution unit proximal to the power supply connector of an electronic component supported within the rack.

FIG. 9 is a plan view of the alternative embodiment of FIG. 8 after the door is pivoted about the door hinge to an open position and the power distribution unit (PDU) is also pivoted about the PDU hinge so that the socket of the PDU remains facing the rack electronic component.

### DETAILED DESCRIPTION OF THE INVENTION

One embodiment of the present invention provides an apparatus comprising a computer storage rack having a plurality of vertically arranged bays for receiving a plurality of electrical power-consuming components, an elongate electrical power distribution unit having a plurality of power distribution sockets vertically spaced along the length of the power distribution unit, and a hinge pivotally coupling the power distribution unit to the rack along a vertical axis, wherein the power distribution unit pivots about the hinge between a position proximal to the bays of the rack and a position distal to the bays of the rack. The apparatus further comprises a plurality of component power supply cables that are resiliently extendable from a collapsed configuration to an extended configuration, wherein each of the component power supply cables is connected between one of the power distribution sockets and an adjacent one of the electrical power-consuming components, and wherein each of the component power supply cables are resiliently extendable to the extended configuration in response to pivoting the power distribution unit to the distal position and resiliently restored to the collapsed configuration in response to pivoting the power distribution unit to the proximal position.

A typical electronic component storage rack may contain a plurality of bays measuring 19 inches in width and have a door hinged to a vertical member of the rack to define a front or rear of the rack. Servers or other electronic components (also generally referred to as “information technology equipment”) that are supportable within the bays of a rack are positioned so that the power supply cables connect to a front or rear panel of the component, data cables connect to a front or rear of the component, and indicators, such as light-emitting diode (LED) indicators, are generally disposed on the front of the component to face towards the front of the rack. The electronic components supportable within bays of the rack are positioned in a common direction to dispose their power supply connectors towards a common side of the rack to facilitate connecting the electronic components to a power distribution unit (PDU) secured to the rack. Typically, the power supply connectors of the electronic components are directed toward the rear of the rack and the PDU is secured in the rear of the rack.

In one embodiment of the present invention, a PDU may be coupled to a rack door to move with the rack door as it pivots about a hinge connected between the door and a vertical member of the rack. When the door of the rack is open to provide access to the electronic components supported in the bays of the rack, power cables connected between the PDU and the electronic components extend to a generally straightened configuration. This may, for example, be beneficial for one or more reasons, such as to facilitate removal of the power supply cable, removal of the corresponding electronic component from a bay of the rack, or installation or removal of data cables. When the rack door is closed, the power supply cables collapse to a compact collapsed configuration, such as a U-shaped, coiled, zigzagged or tortuous configuration, to compactly store the power cable in a small space without obstructing airflow pathways through the electronic components.

In one embodiment, each power supply cable is predisposed to collapse to a predetermined compact configuration that prevents portions of the power supply cable from obstructing airflow pathways within the rack. In one embodiment, each power supply cable may be molded in the collapsed configuration so that it is extendable, by application of an extending force, from the collapsed configuration to the extended configuration or, alternately, each power supply cable may comprise one or more spring elements that is elastically deformable from a collapsed configuration to an extended configuration by application of an extending force.

Another embodiment of the present invention provides an elongate PDU having a main power supply cable at a first end, a plurality of power distribution sockets spaced along a portion of the length of the PDU, and a hinge for pivotally coupling the PDU to a vertical member of the rack. The main power supply cable of the PDU is connected to an electrical power source to supply electrical current to each of the power distribution sockets. A plurality of component power supply cables may be connected at a PDU end to a power distribution socket on the PDU and connected at a component end to an electronic component supported within an adjacent bay of the rack. The extended length of the power supply cable is minimized by selecting the power distribution socket of the PDU that is at the same or about the same vertical elevation as the corresponding bay of the rack supporting the electronic component.

Another embodiment of the present invention provides an elongate PDU having a main power supply cable at a first end, a plurality of power distribution sockets spaced along a portion of the PDU, and a hinge pivotally coupling a door to a vertical member of a rack, wherein the PDU is secured to the door. The main power supply cable is connected to a power source to supply electrical current to each of the power distribution sockets, and a component power supply cable may be connected at a PDU end into a power distribution socket of the PDU and connected at a component end to an electronic component supported in an adjacent bay of the rack.

Another embodiment of the present invention provides an elongate PDU having a main power supply cable at a first end, a plurality of power distribution sockets spaced along a portion of the PDU, and a PDU hinge for pivotally coupling of the PDU to a door that is pivotally coupled to a vertical member of the rack using a door hinge. The main power supply cable is connected to an electrical power source to supply electrical current to each of the power distribution sockets, and a power supply cable may be connected at a PDU end into a power distribution socket of the PDU and connected at a component end to an adjacent electronic component supported in the rack. With this embodiment of the present invention having a PDU hinge and a door hinge, the power distribution sockets of the PDU may remain disposed towards (i.e., facing) the bays of the rack when the door is pivoted about the door hinge to the open position. The presence of the PDU hinge, in addition to the door hinge, enables the further minimization of the length of the component power supply cables, thereby further preventing obstruction of airflow pathways within the rack when the door is in the closed position.

In one embodiment of the present invention, a plurality of component power supply cables conduct current from a plurality of power distribution sockets spaced along a portion of the PDU to a plurality of power supply connectors on a plurality of electronic components supported in the bays of the rack. In one embodiment, the number of bays within the rack is equal to the number of power distribution sockets spaced along a portion of the PDU. In one embodiment, the power distribution sockets of the PDU are spaced along a portion of the PDU to align a power distribution socket with each of a plurality of bays within the rack. This configuration minimizes the extended length and cost of the component power supply cables.

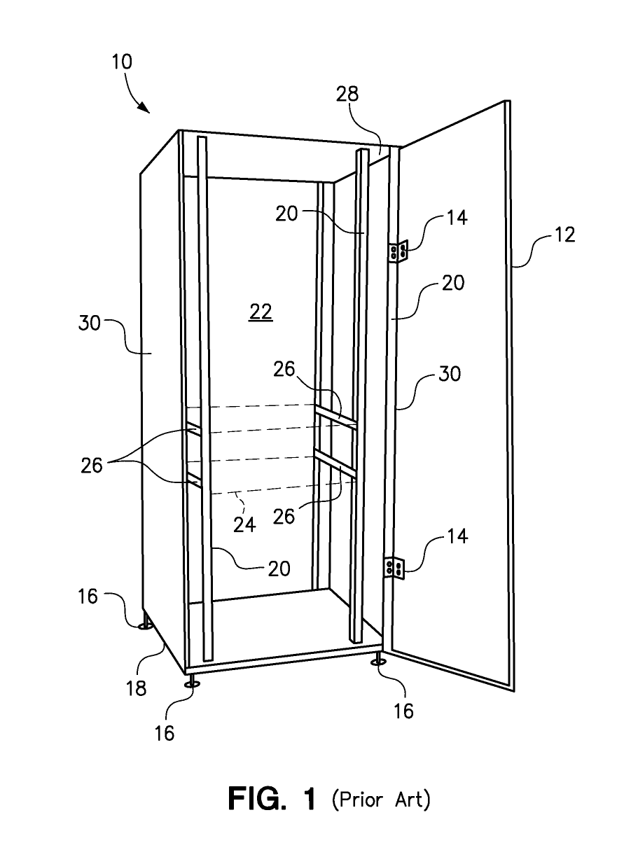

FIG. 1 is a perspective view of a typical electronic component storage rack 10 having a door 12 pivotally coupled to a vertical member 20 of the rack 10 using hinges 14. The rack 10 may be supported using feet 16 or, alternately, rolling members coupled to a bottom end 18 of the rack 10. The rack 10 of FIG. 1 comprises vertical members 20 which may, in one embodiment, be generally parallel one to the others. A pair of vertical members 20 may be spaced apart, for example, 19 inches one from the other, to define a server space 22 therebetween. A bay 24 is provided within the server space 22 by installing horizontal rails 26 between the vertical rails 20 to receive and support an electronic component (not shown), such as a server, in a vertically “stacked” configuration within the rack 10. Only two sets of horizontal rails 26 are shown in FIG. 1 for simplicity, but it will be understood that additional horizontal rails 26 can be provided within the server space 22 to define a plurality of vertically aligned bays 24 to receive and support a plurality of “stacked” electronic components (not shown). One or more air movers (not shown), such as fans, may be included in the rack, in a multi-component chassis, or an individual electronic component in order to provide airflow through the electronic components. The lateral space 28 between the side panel 30 of the rack 10 and the adjacent vertical rail 20 defining the server space 22 may, for example, be used for switch mounting (not shown).

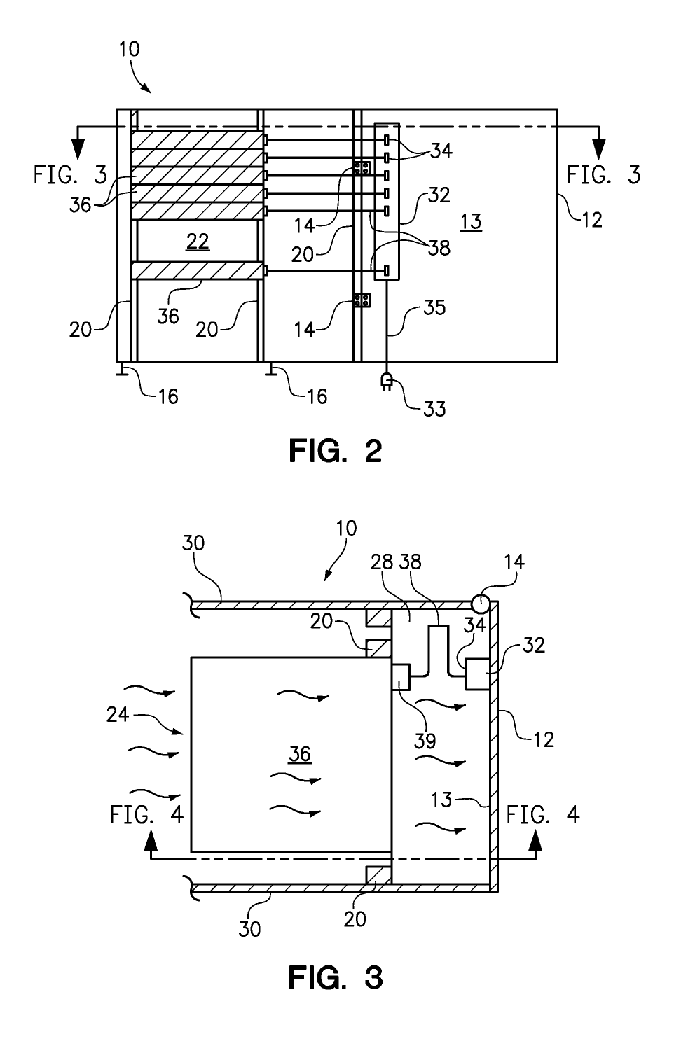

FIG. 2 is an elevation side view of a rack 10 having an elongate PDU 32 connected in a vertical orientation to a door 12 pivotally coupled by hinges 14 to a vertical member 20 of the rack 10. A side panel (not shown—see side panel 30 of FIG. 1) of the rack 10 is omitted from FIG. 2 to reveal the positions of a plurality of electronic components 36 supported within the server space 22 of the rack 10. The PDU 32 has a plurality of power distribution sockets 34 spaced along a portion of the PDU 32 and a main power supply cable 35 terminating at a connector 33. A plurality of component power supply cables 38 are illustrated in an extended configuration and each connected between an electronic component 36 supported within the rack 10 and a power distribution socket 34 on the PDU 32.

FIG. 3 is a schematic plan view of the rack 10 of FIG. 2 after the door 12 of the rack 10 is pivoted about hinge 14 to a closed position. The PDU 32 is connected to an interior side 13 of the door 12. Closure of the door 12 disposes the power distribution sockets 34 on the PDU 32 proximal to the power supply connector 39 on the electronic component 36 in a bay 24 adjacent to the power distribution socket 34 to facilitate collapse of the component power supply cable 38 from the extended configuration, illustrated in FIG. 2, to the collapsed configuration illustrated in FIG. 3. Preferably, the component power supply cables 38 are configured to collapse in a direction that disposes the collapsed component power supply cable 38, or a substantial portion thereof, into the lateral space 28 adjacent to the side panel 30 of the rack 10. The electronic components 36 supported within the rack 10 are structurally similar and, as a result, the power supply connector 39 on each of the electronic components 36 (See FIG. 2) is generally vertically aligned with the power supply connectors 39 on other vertically aligned electronic components 36 stored within the rack 10. Preferably, the pivoting of the door 12 to the closed position collapses all of the component power supply cables 38 so that the component power supply cables 38 are disposed within the lateral space 28 where they will not interfere with airflow through the electronic components 36.

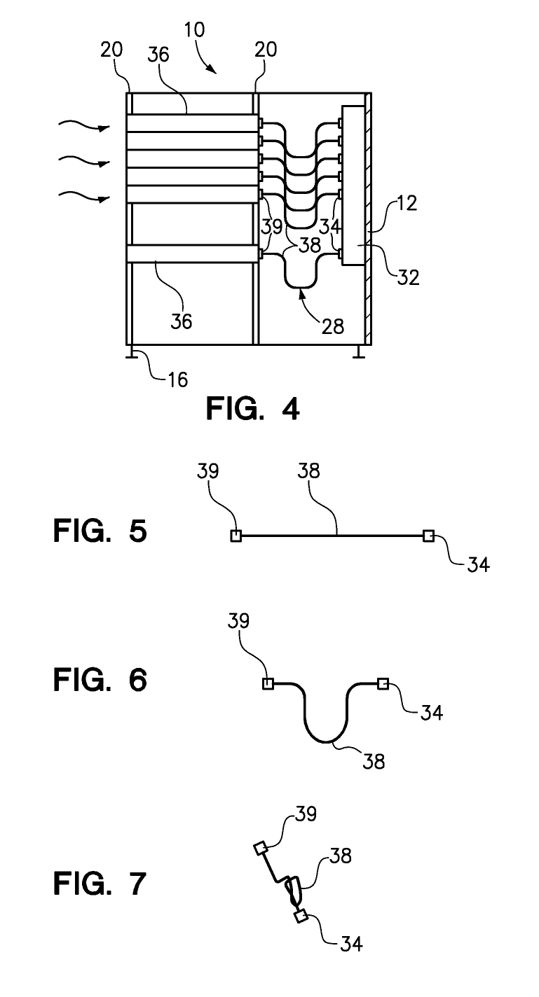

FIG. 4 is the schematic side view of the apparatus in FIG. 3 revealing the plurality of component power supply cables 38 in the collapsed configuration and residing in the lateral space 28 in the rack 10. The capacity of the component power supply cables 38 to collapse for convenient storage in the lateral space 28 facilitates the favorable removal of heat generated within the electronic components 36 by preventing obstruction of airflow pathways, i.e. by preventing blockage of warmed air discharged from the rear of the electronic components 36 or, in other applications, preventing blockage of cooling airflow into the front of the component 36. The collapsed component power supply cables 38 are each disposed intermediate a power distribution socket 34 on the PDU 32 and a power supply connector 39 on an electronic component 36. The generally U-shaped, collapsed configuration of the component power supply cables 38 illustrated in FIG. 4 is generally determined by the characteristics of the component power supply cable 38 and also by the proximity of the power distribution socket 34 of the PDU 32 to the power supply connector 39 when the door 12 is in the closed position shown in FIG. 4. The configuration of the component power supply cables 38 in the collapsed configuration will vary with the distance from the power distribution socket 34 of the PDU 32 to the power supply connector 39 on the electronic component 36 when the door 12 is in the closed position, and the collapsed configuration of the component power supply cable 38 will vary depending on the stiffness of the component power supply cable 38 and the method of manufacture.

FIG. 5 is a diagram of an alternate component power supply cable 38 that can be used in connection with embodiments of the present invention. FIG. 5 illustrates the component power supply cable 38 in an extended configuration corresponding to the position of the door 12 illustrated in FIG. 2. FIG. 5 illustrates the component power supply cable 38 at generally full extension to span the distance from the power distribution socket 34 on the PDU 32 to the power supply connector 39 on the electronic component 36.

FIG. 6 is a diagram of the component power supply cable 38 of FIG. 5 in a collapsed configuration corresponding to the closed position of the door illustrated in FIGS. 3 and 4. The pivoting of the door (not shown) relative to the server rack (not shown) moves the power distribution socket 34 on the PDU (not shown) closer to the power supply connector 39 on the electronic component (not shown) to reduce the distance between the two and to facilitate the collapse of the component power supply cable 38 to a U-shaped configuration.

FIG. 7 is a diagram of yet another embodiment of the power supply cable 38 in a further collapsed configuration corresponding to the closed position of the door 12 (illustrated in FIGS. 3 and 4). The pivoting of the door (not shown) relative to the rack (not shown) to the closed position corresponding to FIGS. 3 and 4 moves the power distribution socket 34 on the PDU (not shown) proximal to the power supply connector 39 on the component (not shown) to minimize the distance between the two and to facilitate the collapse of the power supply cable 38 to a compact configuration, for example, the tortuous configuration illustrated in FIG. 7.

It will be understood that the collapse/extension of the component power supply cables 38 illustrated in FIGS. 5-7 is repeatable. The component power supply cable 38 behaves as a spring element. In other words, the component power supply cable 38 can be forcibly extended from its collapsed configuration to an extended configuration and, by removal of the extending force, it can be substantially restored to its collapsed configuration. The spring element behavior of the component power supply cable 38 eliminates the need for external springs or other cable management devices that consume space, require external connections and interfere with other structures within the rack 10.

The materials selected for the power supply cables 38 must be generally resistant to loss of shape “memory” due to heating by the warm air discharged from the servers and due to cyclic extension and collapse from opening and closing the door 12 of the rack 10. Also, the force required to maintain all of the power supply cables in the extended position must not be so great as to prevent the door 12 from remaining in the open position, for example while individual servers are being cabled, removed, or installed.

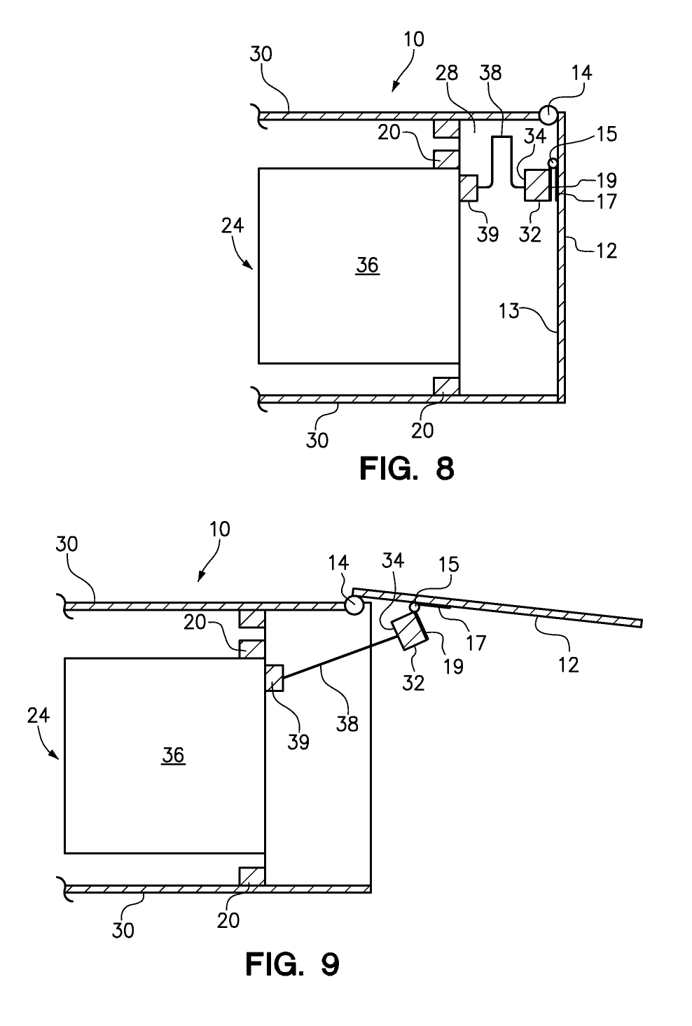

FIG. 8 illustrates an embodiment of the present invention providing an elongate PDU 32 having a main power supply cable (not shown) at a first end (not shown), a plurality of power distribution sockets 34 spaced along a portion of the PDU, and pivotally coupled to a door 12 using a PDU hinge 15. The door 12 is pivotally coupled to the rack 10 using a door hinge 14. A component power supply cable 38 may be connected at a PDU end into a power distribution socket 34 of the PDU 32 and connected at a component end to an adjacent electronic component 36 supported in the rack 10. It should be noted that, with this embodiment of the present invention having a PDU hinge 15 and a door hinge 14, the power distribution sockets 34 of the PDU 32 may remain disposed towards the bays of the rack 10 when the rack door 12 is pivoted about the door hinge 14 to the open position. The presence of the PDU hinge 15, in addition to the door hinge, enables the further minimization of the length of the component power supply cables 38, as is best understood in reference to FIG. 8.

As shown in FIG. 8, the door 12 is closed to position the power distribution unit 32 proximal to the power supply connector 39 of an electronic component 36 supported within the rack 10. The embodiment of the PDU 32 illustrated in FIG. 8 is connected to a PDU plate 19 on the PDU hinge 15 and a door plate 17 of the PDU hinge 15 is connected to the door 12. This arrangement allows the component power supply cable 38 to collapse in response to the door 12 being in the closed position, as illustrated in FIG. 8, and for the component power supply cable 38 to extend in response to the door 12 being moved to the open position, as illustrated in FIG. 9.

FIG. 9 is the plan view of the rack of FIG. 8 after the door 12 is pivoted about the door hinge 14 to an open position to substantially increase the distance between the power distribution unit 32 and the power supply connector 39 on the component 36 supported in the rack 10 to extend the component power supply cable 38 to an extended position. The power distribution unit 32 is also pivoted about the PDU hinge 15 to generally align the power distribution socket 34 of the PDU 32 with the extended component power supply cable 38. The presence of the PDU hinge 15 intermediate the PDU 32 and the door 12 allows the pivoting of the PDU 32 relative to the door 12 so that the socket 34 on the PDU 32 can remain generally angularly aligned with the extended component power supply cable 38 and the component power supply cable will avoid sharp bends or turns that would otherwise require the cable to be longer. It will be understood that the presence of the PDU hinge 15, by enabling the power supply cable 38 to be shorter, thereby further prevents unwanted obstruction of airflow pathways and unwanted consumption of limited space within the rack 10.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, components and/or groups, but do not preclude the presence or addition of one or more other features, integers, steps, operations, elements, components, and/or groups thereof. The terms “preferably,” “preferred,” “prefer,” “optionally,” “may,” and similar terms are used to indicate that an item, condition or step being referred to is an optional (not required) feature of the invention.

The corresponding structures, materials, acts, and equivalents of all means or steps plus function elements in the claims below are intended to include any structure, material, or act for performing the function in combination with other claimed elements as specifically claimed. The description of the present invention has been presented for purposes of illustration and description, but it not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. An apparatus, comprising:
a computer storage rack having a plurality of vertically arranged bays for receiving a plurality of electrical power-consuming components;
an elongate electrical power distribution unit having a plurality of power distribution sockets vertically spaced along the length of the power distribution unit;
a hinge pivotally coupling the power distribution unit to the rack along a vertical axis, wherein the power distribution unit pivots about the hinge between a position proximal to the bays of the rack and a position distal to the bays of the rack;
a plurality of component power supply cables that are resiliently extendable from a collapsed configuration to an extended configuration, wherein each of the component power supply cables is connected between one of the power distribution sockets and an adjacent one of the electrical power-consuming components, and wherein each of the component power supply cables are resiliently extendable to the extended configuration in response to pivoting the power distribution unit to the distal position and resiliently restored to the collapsed configuration in response to pivoting the power distribution unit to the proximal position.

2. The apparatus of claim 1, wherein the hinge pivotally couples the power distribution unit to a rear side of the rack.

3. The apparatus of claim 1, wherein the power distribution unit is secured to a rear door of the rack and the hinge pivotally couples the rear door to the rack.

4. The apparatus of claim 1, wherein the hinge pivotally couples the power distribution unit to a rear door of the rack, wherein the rear door is pivotally coupled to the rack.

5. The apparatus of claim 4, characterized in that the plurality of power distribution sockets are able to remain facing the plurality of bays even as the rear door is pivotally opened.

6. The apparatus of claim 4, wherein the hinge imposes frictional resistance to pivoting so that the torque required to pivot the power distribution unit about the hinge from the distal position to the proximal position exceeds the torque imposed on the power distribution unit by the plurality of extended component power supply cables when the rear door is pivotally opened.

7. The apparatus of claim 1, wherein the plurality of power distribution sockets are vertically spaced along the length of the power distribution unit so that each power distribution socket is aligned with one of the vertically arranged bays.

8. The apparatus of claim 1, wherein each of the component power supply cables is self-biased to a collapsed configuration directed laterally away from airflow pathways of the plurality of electrical power-consuming components.

9. The apparatus of claim 1, wherein each of the plurality of component power supply cables is self-biased to collapse in a common direction towards a lateral side of the rack.

10. The apparatus of claim 1, wherein the collapsed configuration of each of the component power supply cables is a generally U-shaped configuration.

11. The apparatus of claim 1, wherein the collapsed configuration of each of the component power supply cables defines a tortuous path.

12. The apparatus of claim 1, wherein the collapsed configuration of each of the component power supply cables is a generally coiled configuration.

13. The apparatus of claim 1, wherein the collapsed configuration of each of the component power supply cables is a generally zigzagged configuration.
